(19) United States
(12) Patent Application Publication
(10) Pub. No.: US 2010/0065248 A1
(43) Pub. Date: Mar. 18, 2010

(54) HEAT SINK

(75) Inventor: Jin Hsun Liu, Sinjhuang City (TW)

Correspondence Address: NIKOLAI & MERSEREAU, P.A., 900 SECOND AVENUE SOUTH, SUITE 820, MINNEAPOLIS, MN, 55402, US

(73) Assignee: ASIA VITAL COMPONENTS CO., LTD., Sinjhuang City (TW)

(21) Appl. No.: 12/212,042

(22) Filed: Sep. 17, 2008

(51) Int. Cl. F28F 7/02; H05K 7/20

(52) U.S. Cl. 165/80.3; 361/690

(57) ABSTRACT

A heat sink includes a rib section and a plurality of radiating fins spaced on a top face of the rib section. The radiating fins are perpendicularly protruded from the top face of the rib section and orthogonally extended across the rib section with a near middle bottom portion of each of the radiating fins in contact with the top face of the rib section, such that two lateral portions of each of the spaced radiating fins are outward protected from two opposite sides of the rib section to define two comb-shaped air paths. Cold air can flow to spaces below the comb-shaped air paths, and hot air carrying the heat radiated from the radiating fins can upward flow through the comb-shaped air paths and diffused outward as a result of natural air convection around the heat sink. Therefore, the heat sink can have largely upgraded heat dissipation efficiency.

### FIELD OF THE INVENTION

The present invention relates to a heat sink, and more particularly to a heat sink for use in an electronic device.

### BACKGROUND OF THE INVENTION

Due to the progress in semiconductor technique, the volume of integrated circuit (IC) has become smaller and smaller. Electronic elements for IC, such as a central processing unit, would produce more heat per unit time when the operating speed thereof is increased. The produced heat must be timely discharged to avoid rising of temperature and unstable operation. In general, a heat sink is mounted to the central processing unit to help in heat radiation, so as to lower the temperature of the central processing unit and the south and north bridge chips.

FIGS. 1a and 1b are assembled perspective and side views, respectively, of a conventional heat sink 1. As shown, the heat sink 1 includes a radiating base 11 having an upper face 111 and a lower face 112. A plurality of radiating columns 1111 of radiating fins is formed on the upper face 111 of the radiating base 11. The lower face 112 of the radiating base 11 is a flat face for contacting with a heat-producing source 2, so that heat produced by the heat-producing source 2 is transferred to the whole heat sink 1 via the radiating base 11. The heat transferred to the heat sink 1 is then radiated from the radiating columns 1111 and dissipated into ambient air. Moreover, the heat sank 1 is immediately mounted to a top of the heat-producing source 2, and there is only a very narrow space 13 around the heat-producing source 2. The narrow space 13 prevents heat 21 produced by the heat-producing source 2 from smoothly diffusing sideward, bringing the heat 21 to stagnate around the heat-producing source 2. On the other hand, the narrow space 13 and the heat sink 1 itself also prevent cold air 3 near the heat sink 1 from smoothly flowing toward the heat-producing source 2 to carry away the heat 21 produced by the heat-producing source 2. The cold air 3 can at best flow around the heat sink 1 to assist in dissipating heat absorbed by the radiating columns 1111 without providing any help in cooling the heat-producing element 2. Since the produced heat 21 tends to stagnate around the heat-producing element 2 without easily diffusing outward, the temperature of the heat-producing source 2 is forced to rise constantly. This condition would largely lower the heat dissipating efficiency of the heat-producing source 2 and even lead to burnout of the chips in the heat-producing source 2.

In brief, t he conventional heat sink 1 has the following disadvantages: (1) having low heat-dissipating efficiency; (2) easy to cause stagnant hot air around the heat-producing source; (3) not allowing heat produced by the heat-producing source to diffuse efficiently, making the heat-producing source to have low heat-dissipating efficiency; (4) providing low heat exchange efficiency; and (5) failing to enable natural air convection near the heat-producing source.

It is therefore tried by the inventor to develop an improved heat sink to overcome the drawbacks of the conventional heat sink.

### SUMMARY OF THE INVENTION

A primary object of the present invention is to provide a heat sink, which allows the occurrence of natural convection of hot and cold air around the heat sink.

To achieve the above and other objects, the heat sink according to the present invention can be mounted to and in contact with at least one heat-producing element to help in the heat dissipation thereof. The heat sink includes a rib section and a plurality of radiating fins spaced on a top face of the rib section. The radiating fins are perpendicularly protruded from the top face of the rib section and orthogonally extended across the rib section with a near middle bottom portion of each of the radiating fins in contact with the top face of the rib section, such that two lateral portions of each of the spaced radiating fins are outward projected from two opposite sides of the rib section to define two comb-shaped air paths. Cold air can flow to spaces below the comb-shaped air paths, and heat produced by the heat-producing element is transferred to the radiating fins via the rib section and then radiated from the radiating fins into ambient environment. Heat-carrying air can flow through the comb-shaped air paths and diffused outward. With the above arrangements, the heat sink can have largely upgraded heat dissipation performance.

With the above arrangements, the heat sink of the present invention has the following advantages: (1) having good heat dissipating efficiency; (2) preventing heat produced by the heat-producing element from stagnating therearound; (3) enabling high heat exchange efficiency; (4) providing increased heat-dissipating area and space; (5) allowing heat to dissipate in different directions; (6) allowing heat produced by the heat-producing element to diffuse outward at high efficiency; and (7) enabling natural convection of cold and hot fluid or air around the heat sink.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1a is a perspective view showing the mounting of a conventional heat sink to a top of a heat-producing element;

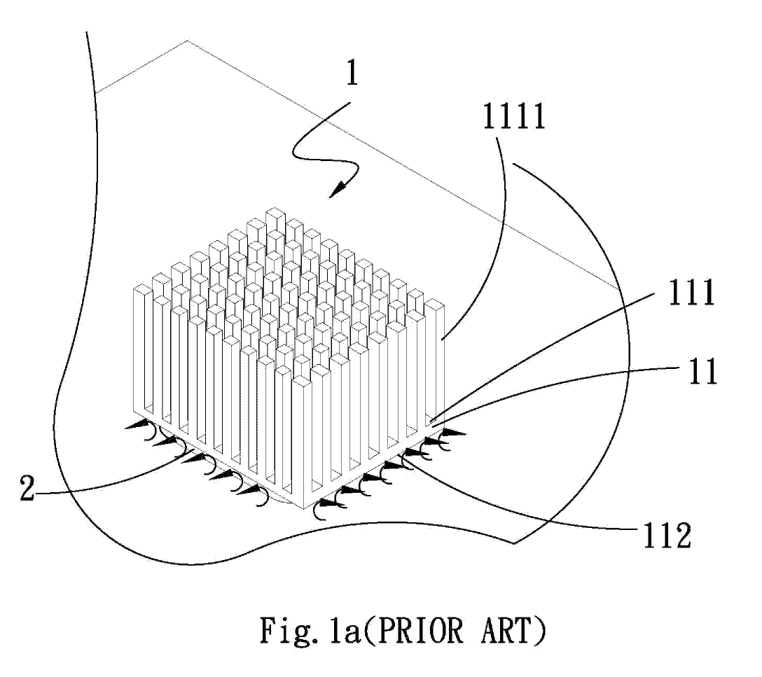

FIG. 1b is a side view of FIG. 1a;

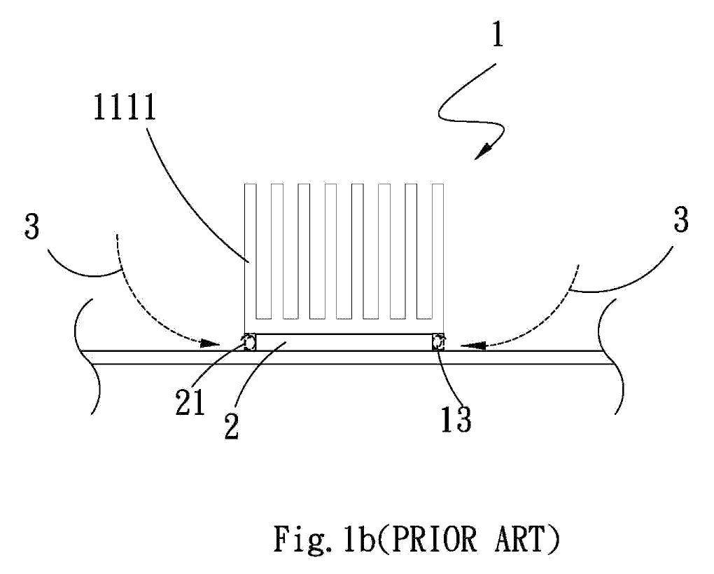

FIG. 2 is an exploded perspective view of a heat sink according to a first embodiment of the present invention before being mounted to a heat-producing element;

FIG. 3 is an assembled view of FIG. 2;

FIG. 4 is a top view of the heat sink of FIG. 3;

FIG. 5a is an assembled perspective view showing the heat sink of FIG. 3 in use;

FIG. 5b is a side view of FIG. 5a;

FIG. 6a is an exploded perspective view of a heat sink according to a second embodiment of the present invention;

FIG. 6b is an assembled view of FIG. 6a; and

FIG. 7 is a front view of a heat pipe for the heat sink of FIGS. 6a and 6b.

### DETAILED DESCRIPTION OF THE PREFERRED EMBODIMENTS

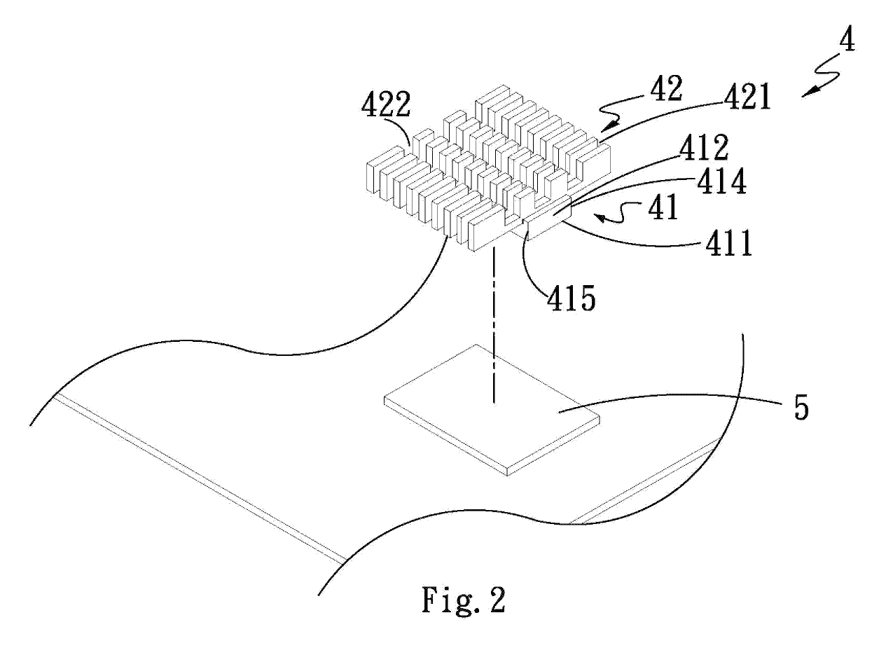

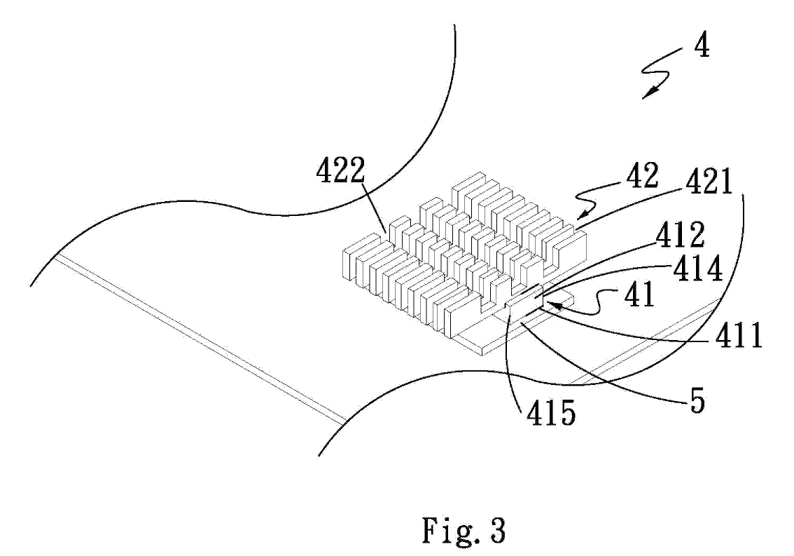

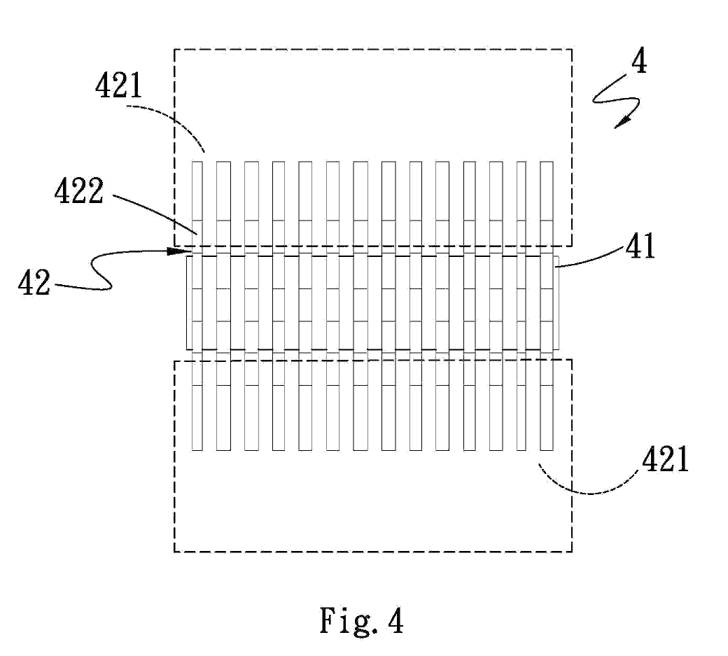

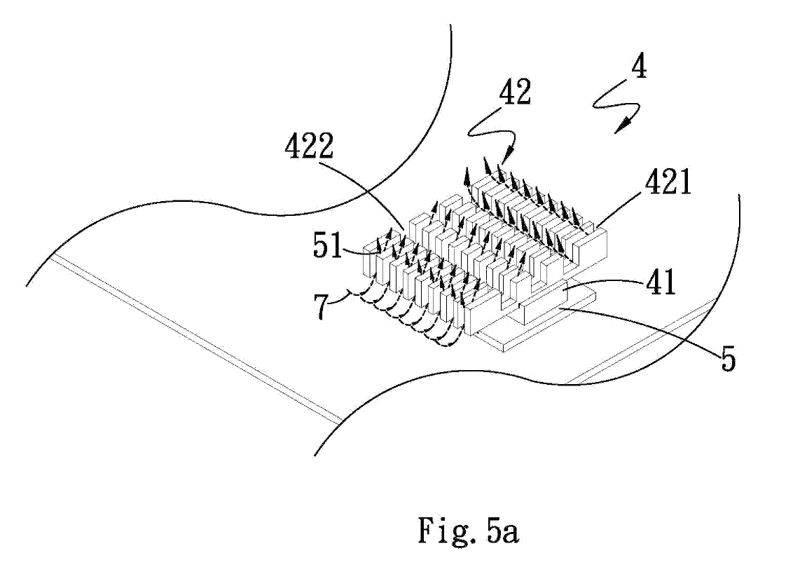

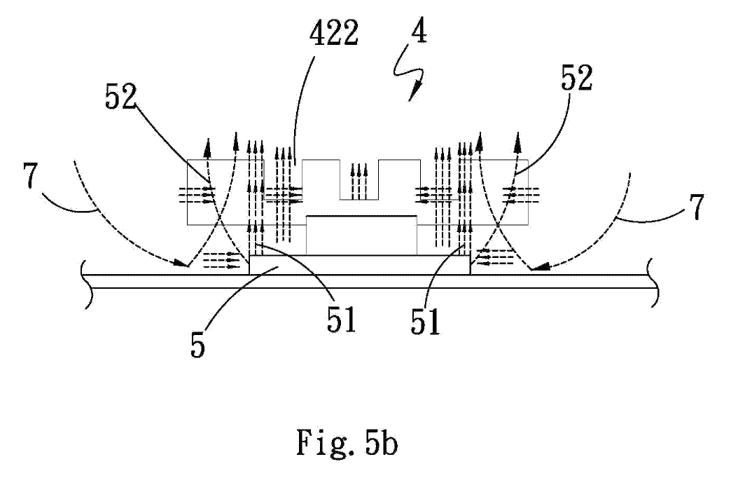

Please refer to FIGS. 2 and 3 that are exploded and assembled perspective views, respectively, showing a heat sink 4 according to a first embodiment of the present invention before and after being mounted to a heat-producing element 5; and to FIG. 4 that is a top view of the heat sink 4; and to FIGS. 5a and 5b that are perspective and side views, respectively, showing the heat sink 4 in use. As shown, the heat sink 4 in the first embodiment includes a rib section 41 and a plurality of radiating fins 42 spaced on a top face of the rib section 41. The radiating fins 42 are perpendicularly protruded from the top face of the rib section 41 and orthogonally extended across the rib section 41 with a near middle bottom portion of each of the radiating fins 42 in contact with the top face of the rib section 41. That is, the spaced radiating fins 42 each have two lateral portions that are not in contact with the rib section 41 but are outward projected from two opposite sides of the rib section 41, such that two comb-shaped air paths 421 are defined at two outer sides of the rib section 41. Therefore, the heat sink 4 with the above-described rib section 41 and radiating fins 42 looks like a fishbone when being viewed from a top thereof, as can be seen in FIG. 4. Cold fluid or air 7 flowing to a bottom side of the two lateral portions of the spaced radiating fins 42 can puss through the comb-shaped air paths 421 to carry away heat radiated from the heat sink 4. The radiating fins 42 are correspondingly formed with at least one notch, so that the notches correspondingly formed on the radiating fins 42 together form a channel 422 extended in a direction perpendicular to the radiating fins 42 and communicating with the comb-shaped air paths 421. It is noted the channel 422 has a bottom that is located above a bottom of each of the radiating fins 42 by a predetermined distance. With the forming of the channel 422, the radiating fins 42 can have increased heat-radiating area.

The heat sink 4 is mounted on a heat-producing element 5 with a bottom face 411 of the rib section 41 bearing on the heat-producing element 5. Heat 51 produced by the heat-producing element 5 is transferred to the radiating fins 42 via the rib section 41, and then radiated from the radiating fins 42 to diffuse and dissipate into ambient air. The cold fluid or air 7 above or around the heat sink 4 and the heat-producing element 5 can also downward flow through the comb-shaped air paths 42 into the spaces below the lateral portions of the radiating fins 42 to carry away the heat transferred to the radiating fins 42, so that hot fluid our air 52 produced by the heat sink 4 or the heat-producing element 5 can smoothly flow upward or outward to dissipate into ambient air. With these arrangements, the heat sink 4 can have largely enhanced heat-dissipating efficiency.

The hot fluid or air 52 formed around the heat-producing element 5 and the heat sink 4 can also upward flow through the comb-shaped air paths 421 to diffuse upward. Therefore, the hot fluid or air 52 will not stagnate around the heat-producing element 5 or the heat sink 4. Meanwhile, the above-described heat sink 4 enables the occurrence of natural convection of the cold fluid or air 7 and the hot fluid or air 52, which in turn enables the heat sink 4 to have upgraded heat-dissipating efficiency.

The heat sink 4 can be integrally formed to reduce the occurrence of thermal resistance.

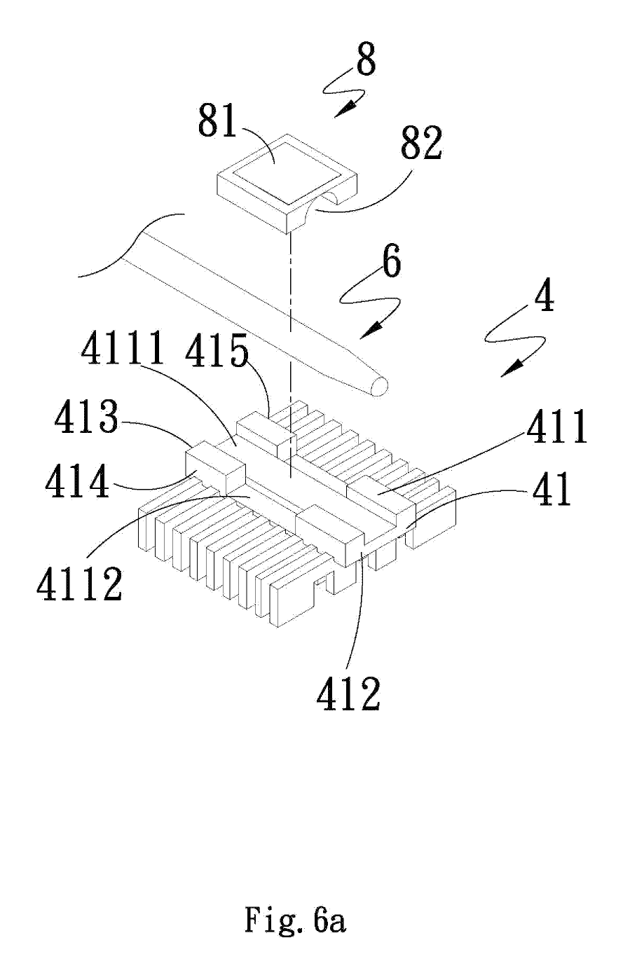

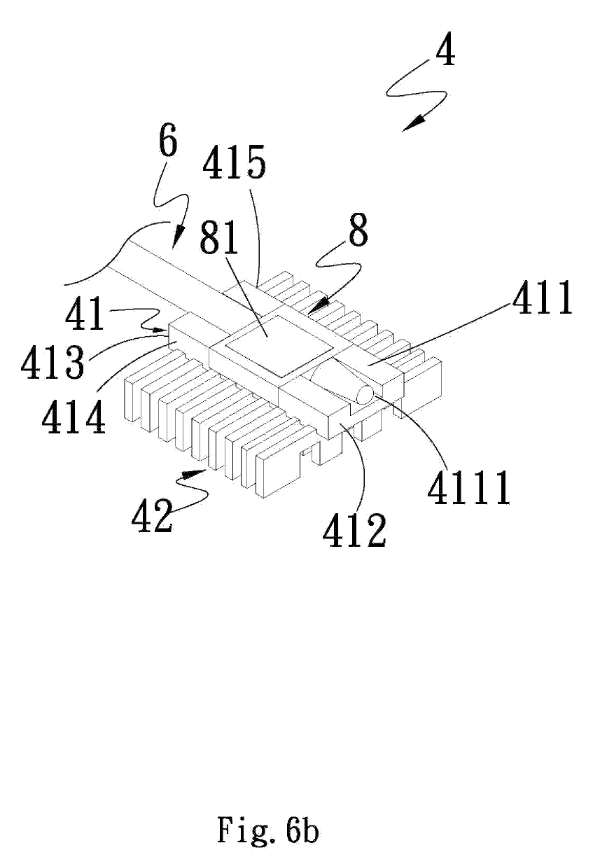

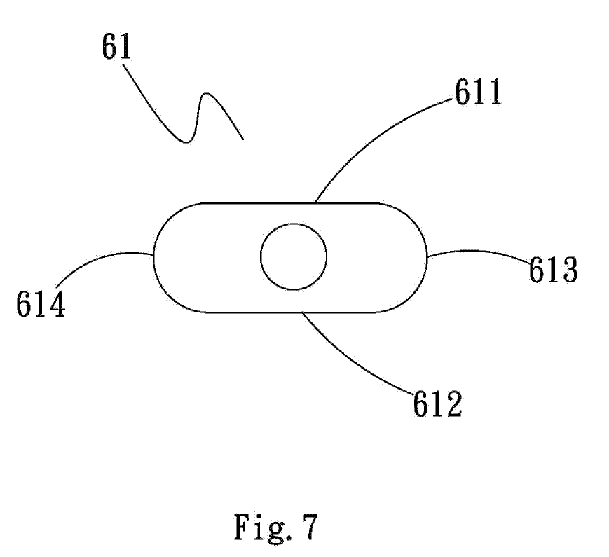

Please refer to FIGS. 6a and 6b that are exploded and assembled perspective views, respectively, of a heat sink 4 according to a second embodiment of the present invention, and to FIG. 7 that is a front view of a heat pipe for the heat sink 4 of the second embodiment. The heat sink 4 in the second embodiment is different from that in the first embodiment in that the bottom face 411 of the rib section 41 is formed with at least one guide channel 4111 longitudinally extended from a front end 412 of the rib section 41 to a rear end 413 thereof, and a recess 4112 transversely extended from a first longitudinal side 414 of the rib section 41 to a second longitudinal side 415 thereof, such that the guide channel 4111 and the recess 4112 orthogonally intersect and communicate with each other.

At least one heat pipe 6 is included in the heat sink 4 of the second embodiment. A heat conduction end 61 of the at least one heat pipe 6 is snugly received in the at least one guide channel 4111. In addition, a bottom plate 8 is snugly fitted in the recess 4112. The bottom plate 8 has a first lace serving as a contact face 81 for contacting with at least one heat-producing element 5, and a second face opposite to the contact face 81 and formed with a longitudinally extended groove 82 for snugly receiving the heat pipe 6 therein. Therefore, when the bottom plate 8 is fitted in the recess 4112, the heat pipe 6 is fixedly held between the guide channel 4111 of the rib section 41 and the groove 82 of the bottom plate 8.

Referring to FIG. 7, which is a front view of the heat pipe 6, the heat conduction end 61 of the heat pipe 6 has two opposite flat contact faces 611, 612 and two opposite lateral faces 613, 614 extended from the contact faces 611, 612. One of the contact faces 611, 612 is bearing on an inner wall surface of the guide channel 4111, while the other one of the contact faces 611, 612 is bearing on a heat-producing element (not shown). With the heat pipe 6, the heat produced by the heat-producing element 5 can be more quickly conducted to thereby upgrade the heat-dissipation efficiency of the heat sink 4.

A heat-conducting bonding agent, such as tin paste, can be applied between the heat pipe 6 and the guide channel 4111 and the groove 82 to firmly bond the heat pipe 6 to the heat sink 4.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat sink, comprising a rib section and a plurality of radiating fins spaced on a top face of the rib section; the radiating fins being perpendicularly protruded from the top face of the rib section and orthogonally extended across the rib section with a near middle bottom portion of each of the radiating fins in contact with the top face of the rib section, such that two lateral port ions of each of the spaced radiating fins are not in contact with the rib section but are outward projected from two opposite sides of the rib section to define two comb-shaped air paths at two outer sides of the rib section; whereby cold fluid or air flowing to a bottom side of the two lateral portions of the spaced radiating fins can upward pass through the comb-shaped air paths to carry away heat radiated from the heat sink.

2. The heat sink as claimed in claim 1, wherein the radiating fins are correspondingly formed with at least one notch, so that the notches correspondingly formed on the radiating fins together form a channel extended in a direction perpendicular to the radiating fins and communicating with the comb-shaped air paths.

3. The heat sink as claimed in claim 2, wherein the at least one channel has a bottom that is located above a bottom of each of the radiating fins by a predetermined distance.

4. The heat sink as claimed in claim 1, wherein the rib section is formed at a bottom face with at least one guide channel and a recess, the guide channel and the recess intersecting and communicating with each other and the guide channel having at least one heat pipe received therein.

5. The heat sink as claimed in claim 1, wherein the rib section and the radiating fins are integrally formed.

6. The heat sink as claimed in claim 4, further comprising a bottom plate snugly fitted in the recess; the bottom plate having a contact face for contacting with at least one heat-producing element, and a groove formed on another face opposite to the contact face for receiving the heat pipe therein.

7. The heat sink as claimed in claim 6, wherein a heat-conducting bonding agent is applied between the heat pipe and the rib section and the bottom plate.
